(19) United States
(12) Patent Application Publication
(10) Pub. No.: US 2013/0236844 A1
(43) Pub. Date: Sep. 12, 2013

(54) SUBSTRATE CARRIER AND SELENIZATION PROCESS SYSTEM THEREOF

(71) Applicants: Shih-Wei Lee, Kaohsiung City (TW); Ching-Ju Lin, Kaohsiung City (TW); Chin-Yuan Chung, Hsinchu City (TW); Ming-Hung Lin, Pingtung County (TW); Wei-Min Huang, Taipei City (TW); Chen-Hai Chiu, Hsinchu County (TW)

(72) Inventors: Shih-Wei Lee, Kaohsiung City (TW); Ching-Ju Lin, Kaohsiung City (TW); Chin-Yuan Chung, Hsinchu City (TW); Ming-Hung Lin, Pingtung County (TW); Wei-Min Huang, Taipei City (TW); Chen-Hai Chiu, Hsinchu County (TW)

(73) Assignee: AXUNTEK SOLAR ENERGY, Pingtung County (TW)

(21) Appl. No.: 13/465,039

(22) Filed: May 7, 2012

(30) Foreign Application Priority Data
Mar. 6, 2012 (TW) 101107433

(51) Int. Cl. F27D 5/00

(52) U.S. Cl. 432/1; 432/253

(57) ABSTRACT

A substrate carrier is used for carrying a plurality of back electrode substrates into a furnace. Each back electrode substrate has a precursor layer formed thereon. The furnace is used for providing a process gas to react with the precursor layer, so as to form a photoelectric transducing layer on each back electrode substrate. The substrate carrier includes a heat-resistant metal frame and a first protective layer. The heat-resistant metal frame has a plurality of slots for supporting the plurality of back electrode substrates. The first protective layer is formed on the heat-resistant metal frame for preventing a chemical reaction of the heat-resistant metal frame with the process gas.

### BACKGROUND OF THE INVENTION

1. Field of the Invention

The present invention relates to a substrate carrier and a selenization process system, and more specifically, to a substrate carrier having a heat-resistant metal frame with a protective layer formed thereon and a selenization process system thereof.

2. Description of the Prior Art

Generally, in a manufacturing process of a CIGS (copper indium gallium selenide) solar battery, a conventional method of forming a CIGS/CIGSS (copper indium gallium selenide sulfide) absorber film involves utilizing a co-evaporation process or a selenization process.

In the selenization process, a substrate carrier for carrying back electrode substrates into a selenization furnace is usually made of quartz or ceramics, so that the substrate carrier could have heat resistant and gas-corrosion (e.g. sulfide gas) resistant characteristics. However, since quartz and ceramics are expensive and brittle, the aforesaid design in which the substrate carrier is made of quartz or ceramics may greatly increase the material cost of the solar battery manufacturing process. Furthermore, the substrate carrier may be damaged easily by collision with other process components during the transportation process, so as to influence the productive capacity of the solar battery manufacturing process and result in unnecessary loss.

### SUMMARY OF THE INVENTION

The present invention provides a substrate carrier for carrying a plurality of back electrode substrates into a furnace. Each back electrode substrate has a precursor layer formed thereon. The furnace is used for providing a process gas to react with the precursor layer so as to form a photoelectric transducing layer on each back electrode substrate. The substrate carrier includes a heat-resistant metal frame and a first protective layer. The heat-resistant metal frame has a plurality of slots for supporting the plurality of back electrode substrates. The first protective layer is formed on the heat-resistant metal frame for preventing a chemical reaction of the heat-resistant metal frame with the process gas.

The present invention further provides a selenization process system. The selenization process system includes a plurality of back electrode substrates, a furnace, and a substrate carrier. Each back electrode substrate has a precursor layer formed thereon. The furnace includes a reaction chamber, a gas input pipeline, and a heating device. The gas input pipeline is used for providing a process gas to the reaction chamber. The heating device is used for heating the reaction chamber to make the process gas react with the precursor layer so as to form a photoelectric transducing layer on each back electrode substrate. The substrate carrier is used for carrying the plurality of back electrode substrates into the furnace. The substrate carrier includes a heat-resistant metal frame and a first protective layer. The heat-resistant metal frame has a plurality of slots for supporting the plurality of back electrode substrates. The first protective layer is formed on the heat-resistant metal frame for preventing a chemical reaction of the heat-resistant metal frame with the process gas.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an inner diagram of a selenization process system according to an embodiment of the present invention.

FIG. 2 is a diagram of a substrate carrier in FIG. 1.

FIG. 3 is a sectional diagram of the substrate carrier in FIG. 2 along a sectional line A-A′.

FIG. 4 is a sectional diagram of a substrate carrier according to another embodiment of the present invention.

### DETAILED DESCRIPTION

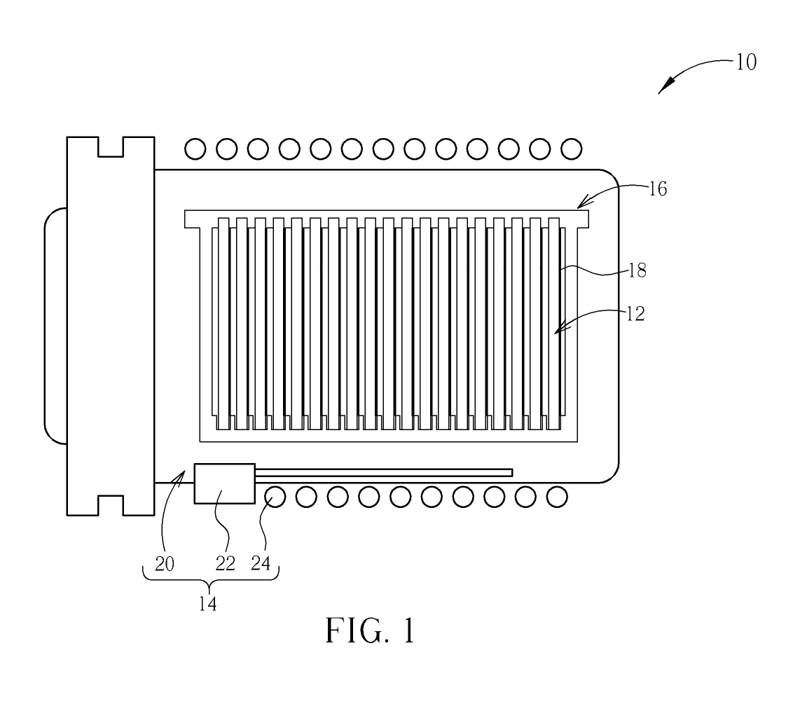

Please refer to FIG. 1, which is an inner diagram of a selenization process system 10 according to an embodiment of the present invention. The selenization process system 10 is applied to a solar battery manufacturing process. As shown in FIG. 1, the selenization process system 10 includes a plurality of back electrode substrates 12, a furnace 14, and a substrate carrier 16. In general, the substrate of the back electrode substrate 12 could be a soda-lime glass, and the back electrode of the back electrode substrate 12 could be made of molybdenum (Mo) material. Each back electrode substrate 12 has a precursor layer 18 formed thereon. In this embodiment, the precursor layer 18 is an IB-group and IIIA-group chemical compound layer, such as Cu—Ga/In, Cu—Ga—In alloy, or Cu—Ga—In stacked layer. As for the process of forming the back electrode substrate 12 and the precursor layer 18, it is commonly seen in the prior art. In brief, a sputtering machine or other electrode forming technology is utilized to form the back electrode on the substrate of the back electrode substrate 12, and a thin-film deposition technology or other thin-film forming technology is then utilized to form the precursor layer 18 on the back electrode of the back electrode substrate 12.

The furnace 14 could be a conventional selenization equipment for a selenization process of a solar battery. As shown in FIG. 1, the furnace 14 includes a reaction chamber 20, a gas input pipeline 22, and a heating device 24. The gas input pipeline 22 is used for providing a process gas (e.g. H₂Se or H₂S) to the reaction chamber 20 to react with the precursor layer 18. The heating device 24 is used for heating the reaction chamber 20 to a temperature (about 450° C. to 550° C.) in which the process gas could react with the precursor layer 18 of each back electrode substrate 12 respectively to form a corresponding photoelectric transducing layer. The photoelectric transducing layer could be, for example, a chalcopyrite structure of copper indium selenide (CIS), copper indium sulfide (CIS), copper indium gallium selenide (CIGS), or copper indium gallium selenide sulfide (CIGSS). As for the related component designs of the furnace 14, they are commonly seen in the prior art and the related description is therefore omitted herein.

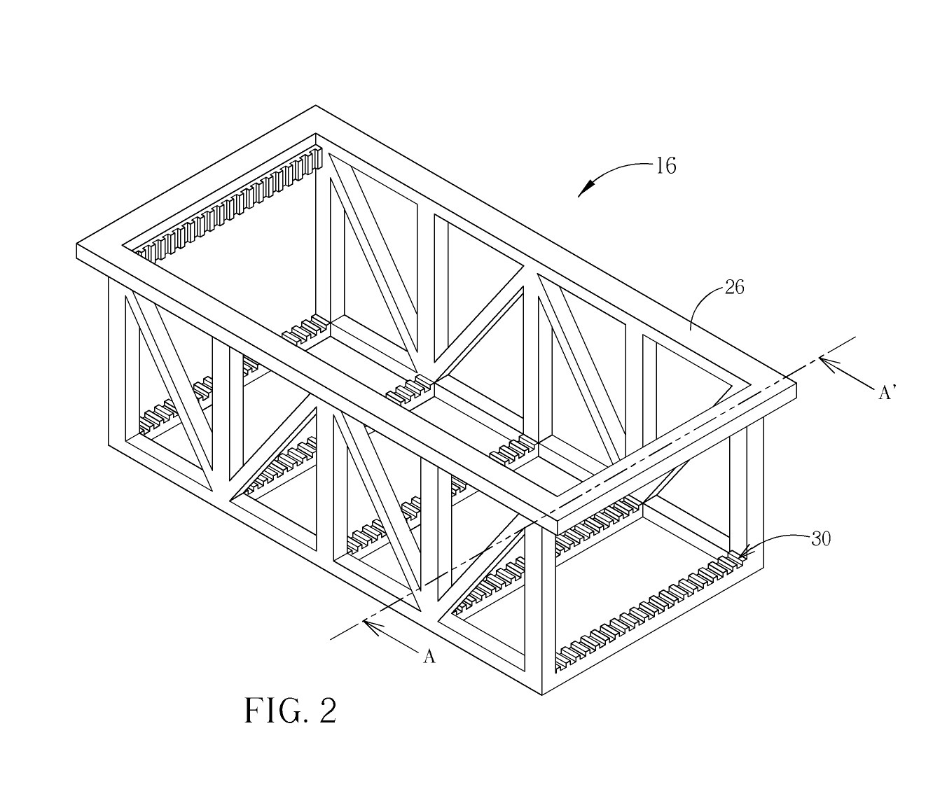

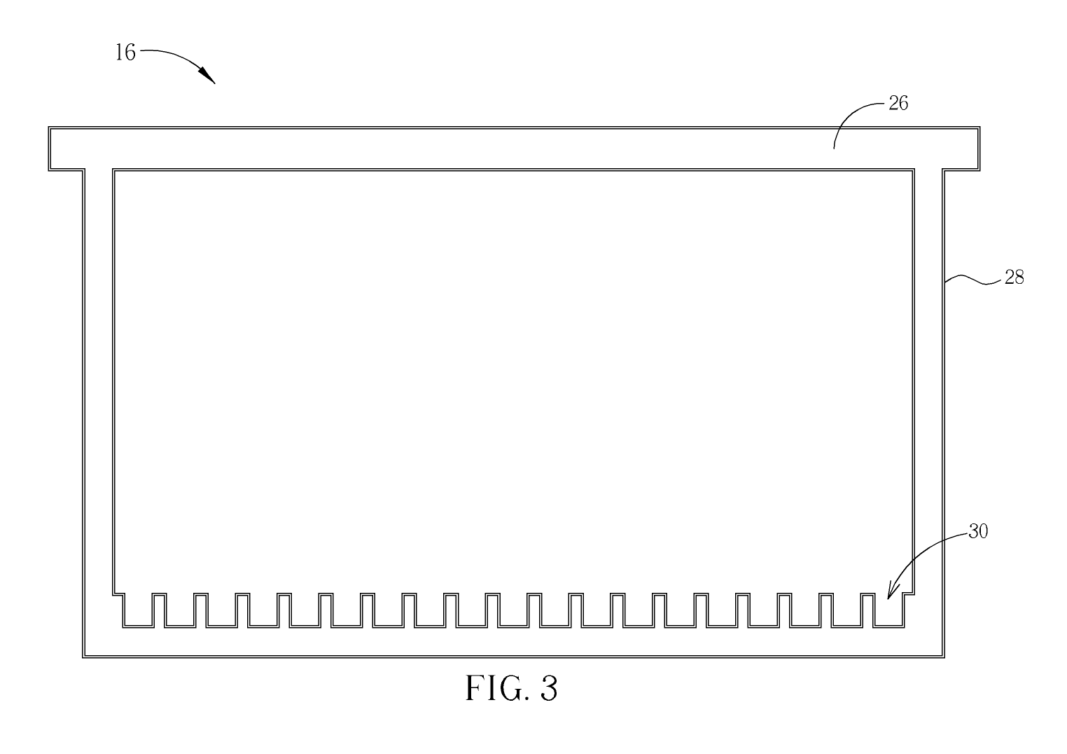

More detailed description for the design of the substrate carrier 16 is provided as follows. Please refer to FIG. 1, FIG. 2, and FIG. 3. FIG. 2 is a diagram of the substrate carrier 16 in FIG. 1. FIG. 3 is a sectional diagram of the substrate carrier 16 in FIG. 2 along a sectional line A-A′. The substrate carrier 16 is used for carrying the plurality of back electrode substrates 12 into the reaction chamber 20 (as shown in FIG. 1) to perform the aforesaid selenization process. The substrate carrier 16 includes a heat-resistant metal frame 26 and a first protective layer 28. In this embodiment, the heat-resistant metal frame 26 is preferably made of metal material capable of withstanding the high temperature (about 450° C. to 550° C.) of the aforesaid selenization process, such as molybdenum material, titanium (Ti) material, tantalum (Ta) material, or tungsten (W) material, so as to prevent the heat-resistant metal frame 26 form melting in the high temperature of the reaction chamber 20. Furthermore, as shown in FIG. 2, the heat-resistant metal frame 26 has a plurality of slots 30 for supporting the back electrode substrates 12, so that the back electrode substrates 12 could be conveyed steadily with the substrate carrier 16 into the reaction chamber 20 of the furnace 14 by a conventional automatic equipment (e.g. a robot arm or a conveyor belt).

In addition, the first protective layer 28 is formed on the heat-resistant metal frame 26 (as shown in FIG. 3) and is preferably an oxide layer, a nitride layer, or a selenium layer in this embodiment. To be more specific, a conventional surface treatment (e.g. thermal processing or chemical processing) could be performed on the heat-resistant metal frame 26 to forma gas-corrosion resistant layer (i.e. the first protective layer 28) on the heat-resistant metal frame 26, so as to prevent corrosion of the heat-resistant metal frame 26 caused by the process gas or prevent the heat-resistant metal frame 26 from reacting with the process gas to generate harmful chemical compound. Thus, the forming quality of the photoelectric transducing layer could be further improved.

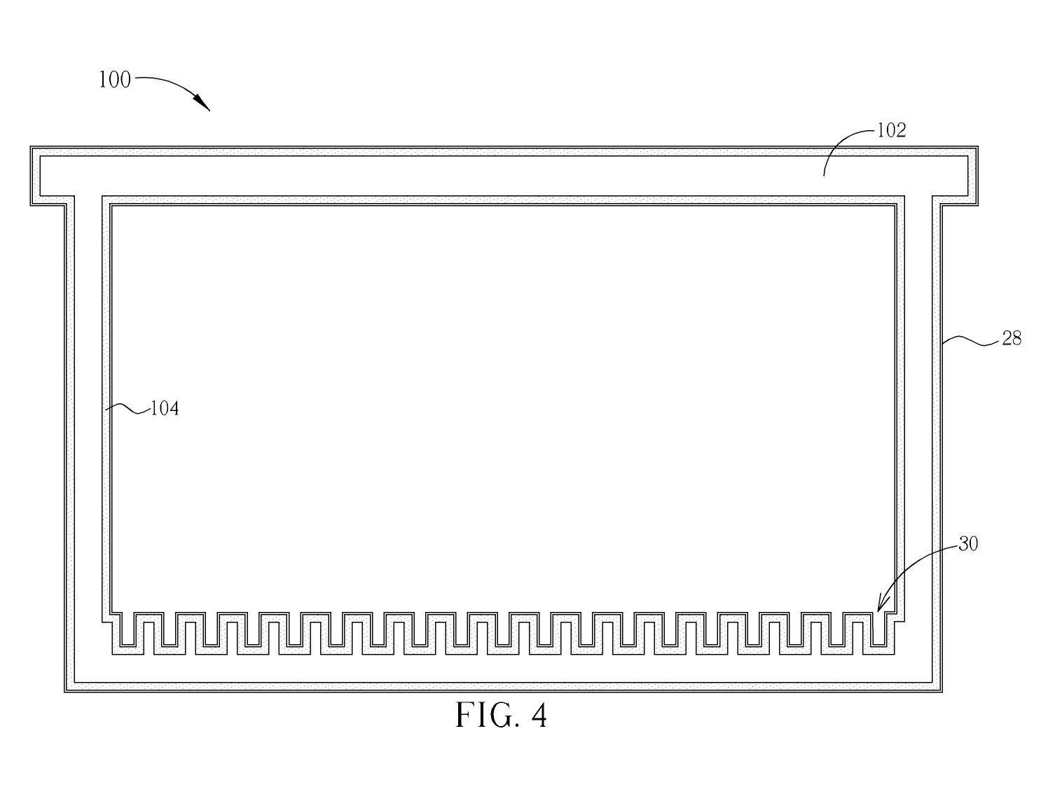

It should be mentioned that the heat resistant design of the heat-resistant metal frame is not limited to the aforesaid embodiment. Please refer to FIG. 4, which is a sectional diagram of a substrate carrier 100 according to another embodiment of the present invention. Components both mentioned in this embodiment and the aforesaid embodiment represent components with similar structures or functions, and the related description is therefore omitted herein. The major difference between the substrate carrier 100 and the substrate carrier 16 is material of the heat-resistant frame and additional disposal of another protective layer. As shown in FIG. 4, the substrate carrier 100 includes a heat-resistant metal frame 102 and the first protective layer 28. The heat-resistant metal frame 102 has the plurality of slots 30 for supporting the back electrode substrates 12. The heat-resistant metal frame 102 further has a second protective layer 104 formed thereon corresponding to the first protective layer 28. The second protective layer 104 could be made of heat-resistant metal material, such as molybdenum material, titanium material, tantalum material, or tungsten material, and a thickness of the second protective layer 104 is about 100 μm to 500 μm. In this embodiment, the heat-resistant metal frame 102 could be made of conventional metal material, such as stainless steel material. As for forming of the second protective layer 104, a conventional surface treatment (e.g. thermal processing or chemical processing) could be performed on the heat-resistant metal frame 102 to form a heat resistant layer (i.e. the second protective layer 104) on the heat-resistant metal frame 102. In such a manner, besides the gas-corrosion resistant characteristic due to utilizing the first protective layer 28, the substrate carrier 100 could further have the heat resistant characteristic via the design in which the second protective layer 104 is additionally formed on the heat-resistant metal frame 102 (as shown in FIG. 4). In addition, since the heat-resistant metal frame 102 could just be made of conventional metal material rather than heat-resistant metal material in this embodiment, the material cost of the solar battery manufacturing process could be further reduced.

Compared with the prior art, via the aforesaid design in which the substrate carrier has the heat-resistant metal frame and the protective layer formed on the heat-resistant metal frame, the substrate carrier of the present invention could have heat resistant and gas-corrosion resistant characteristics to prevent the heat-resistant metal frame from melting in the high temperature of the selenization process, being corroded by the process gas, or reacting with the process gas to form harmful chemical compound, so that the forming quality of the photoelectric transducing layer could be improved. Furthermore, since the heat-resistant metal frame is made of metal material rather than quartz or ceramics material, the present invention could not only reduce the material cost of the solar battery manufacturing process, but also increase the overall structural strength of the substrate carrier due to high strength and high rigidity of metal material. Thus, since the prior art problem that the substrate carrier may be damaged easily by collision with other process components during the transportation process could be solved accordingly, an automation design could be further applied to the selenization process system of the present invention for increasing the productive capacity of the solar battery manufacturing process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A substrate carrier for carrying a plurality of back electrode substrates into a furnace, each back electrode substrate having a precursor layer formed thereon, the furnace being used for providing a process gas to react with the precursor layer so as to form a photoelectric transducing layer on each back electrode substrate, the substrate carrier comprising:
a heat-resistant metal frame having a plurality of slots for supporting the plurality of back electrode substrates; and
a first protective layer formed on the heat-resistant metal frame for preventing a chemical reaction of the heat-resistant metal frame with the process gas.

2. The substrate carrier of claim 1, wherein the first protective layer is an oxide layer, a nitride layer, or a selenium layer.

3. The substrate carrier of claim 1, wherein the heat-resistant metal frame has a second protective layer formed thereon, and the second protective layer is made of molybdenum (Mo) material, titanium (Ti) material, tantalum (Ta) material, or tungsten (W) material.

4. The substrate carrier of claim 3, wherein the heat-resistant metal frame is made of stainless steel material.

5. The substrate carrier of claim 1, wherein the heat-resistant metal frame is made of molybdenum material, titanium material, tantalum material, or tungsten material.

6. A selenization process system comprising:
a plurality of back electrode substrates, each back electrode substrate having a precursor layer formed thereon;
a furnace comprising:
a reaction chamber;
a gas input pipeline for providing a process gas to the reaction chamber; and
a heating device for heating the reaction chamber to make the process gas react with the precursor layer so as to form a photoelectric transducing layer on each back electrode substrate; and
a substrate carrier for carrying the plurality of back electrode substrates into the furnace, the substrate carrier comprising:
a heat-resistant metal frame having a plurality of slots for supporting the plurality of back electrode substrates; and
a first protective layer formed on the heat-resistant metal frame for preventing a chemical reaction of the heat-resistant metal frame with the process gas.

7. The selenization process system of claim 6, wherein the first protective layer is an oxide layer, a nitride layer, or a selenium layer.

8. The selenization process system of claim 6, wherein the heat-resistant metal has a second protective layer formed thereon, and the second protective layer is made of molybdenum material, titanium material, tantalum material, or tungsten material.

9. The selenization process system of claim 8, wherein the heat-resistant metal frame is made of stainless steel material.

10. The selenization process system of claim 6, wherein the first protective layer is made of molybdenum material, titanium material, tantalum material, or tungsten material.

11. The selenization process system of claim 6, wherein the precursor layer is an IB-group and IIIA-group chemical compound layer.

12. The selenization process system of claim 6, wherein the process gas is a hydrogen selenide (H₂Se) gas or a hydrogen sulfide (H₂S) gas.
